(19) United States
(12) Patent Application Publication
(10) Pub. No.: US 2005/0150542 A1
(43) Pub. Date: Jul. 14, 2005

(54) Stable Three-Terminal and Four-Terminal Solar Cells and Solar Cell Panels Using Thin-Film Silicon Technology

(76) Inventor: Arun Madan, Golden, CO (US)

Correspondence Address: HOLLAND & HART, LLP, 555 17TH STREET, SUITE 3200, DENVER, CO, 80201, US

(21) Appl. No.: 10/905,545

(22) Filed: Jan. 10, 2005

Related U.S. Application Data
(60) Provisional application No. 60/536,151, filed on Jan. 13, 2004.

(51) Int. Cl. H01L 31/00

(52) U.S. Cl. 136/255; 136/249; 438/74

(57) ABSTRACT

Three-terminal (3-T) and four-terminal (4-T) thin-film, Si-based, multi-junction solar cells, and solar cell panels wherein multiple solar cells are electrically connected in series, in which current-matching-constraints are released from the two stacked cells that make up each solar cell, wherein the two stacked cells (i.e. a first n-i-p a-Si:H cell considered in the direction of light penetration, and a second stable, low band gap material p-i-n cell, such as a p-i-n nc-Si:H cell considered in the direction of light penetration) are carried by a substrate having a top-disposed and ultra-thin (about 1000 A thick) a-Si:H solar cell where instability is not an issue, the invention having the potential of attaining η>16%. In an embodiment the solar cells and panels are manufactured using a cluster tool manufacturing system wherein a robotic arm transports a reel-to-reel substrate-cassette to selected deposition chambers, the substrate-cassette containing a flexible substrate such as a stainless steel foil or a plastic web. In another embodiment a rigid substrate such as glass or rigid stainless steel is used.

### RELATED PATENT APPLICATION AND PATENTS

This application claims the priority of U.S. Provisional Patent Application Ser. No. 60/536,151, filed on Jan. 13, 2004, entitled THREE TERMINAL AND FOUR TERMINAL SOLAR CELLS, SOLAR CELL PANELS, AND METHOD OF MANUFACTURE, incorporated herein by reference. The following United States patents are included herein by reference: U.S. Pat. No. 6,488,777 issued on Dec. 3, 2002, entitled SEMICONDUCTOR VACUUM DEPOSITION SYSTEM AND METHOD HAVING A REEL-TO-REEL SUBSTRATE CASSETTE; U.S. Pat. No. 6,258,408 issued on Jul. 10, 2002, entitled SEMICONDUCTOR VACUUM DEPOSITION SYSTEM AND METHOD HAVING A REEL-TO-REEL SUBSTRATE CASSETTE; U.S. Pat. No. 5,016,562 issued on May 21, 1991, entitled MODULAR CONTINUOUS VAPOR DEPOSITION SYSTEM; and U.S. Pat. No. 4,763,602 issued on Aug. 16, 1988, entitled THIN FILM DEPOSITION APPARATUS INCLUDING A VACUUM TRANSPORT MECHANISM.

### BACKGROUND OF THE INVENTION

Electronic devices such as solar cells can be fabricated on rigid or flexible substrates using a multi-chamber (cluster tool) system wherein a number of process chambers are situated around a central chamber that houses a movable robotic arm, the robotic arm being used to transport the substrate from one chamber to another in order to complete the multi-layer-structure of the electronic device. Since the chambers are physically separated by gate valves, high performance electronic devices are produced. For example see U.S. Pat. No. 6,258,408.

There is a need for highly efficient, low cost and stable thin-film silicon (Si) solar cells and solar cell panels that include either a rigid or a flexible substrate, these solar cells/panels using amorphous silicone (a Si:H) and micro-(or nano) crystalline silicone (nc-Si:H), involving the use of doped and undoped materials that are fabricated using a chemical vapor deposition technique such as plasma enhanced chemical vapor deposition (PECVD).

Conventional deposition systems require that the substrate go through various deposition chambers or zones in one sequence. In some cases these depositions zones are not physically separated, cross contamination occurs, leading to poor device performance, although an attempt can be made to minimize cross contamination by using slits and gas curtains between the deposition zones. After completion of a desired deposition on a given substrate, the substrate is removed, a new substrate is installed, and this new substrate is feed through the deposition system. As electronic devices require several photolithographic steps, the use of long substrates makes the use of precise photolithographic patterning difficult.

Light induced degradation is an impediment to the large scale deployment of a-Si:H based solar panels. This degradation is strongly dependant upon the thickness of the solar cells, and can be circumvented to a certain extant by using multi-junctions (MJs), but at the expense of complex fabrication.

MJ solar cell devices provide several solar cells that are stacked on top of each other, with the cells having differing band gaps (and thickness) to absorb a wider portion of the solar spectrum (for example, three-layer a-SiH/a-SiGeH/a-SiGeH solar cells). A two-terminal (2-T) MJ device requires the same magnitude current from each constituent cell, necessitates the use of relatively thick a-SiH junctions (˜2000 A), and the device generally degrades by ˜20%.

Further, fabrication of SiGe:H requires the use of an expensive GeH₄ gas, and since gas utilization during production is normally <10%, a cost reduction in the production of these solar cells/panels is difficult to realize.

Hence, the use of 2-T MJ solar cells, with stable micro-(or nano-) crystalline Si (nc-SiH) as the bottom cell and a-Si:H as the top (or light-entering) cell, has attracting attention (termed “micro-morph”). Such MJ (or tandem) solar cells can produce an initial efficiency (η) of ˜14.5% in a small size or area module (about 3 cm²), and an efficiency ˜12% in large area modules. However, this structure also contains a thick (˜4000 A) a-Si:H layer (due to the required current-matching), and as a result the majority of the power (˜70%) emanates from the unstable and thick a-Si:H portion, with inevitable degradation when the structure is light-illuminated.

Thin film solar cells in many cases employ tandem junctions to increase the cell's power and stability, especially when amorphous silicon type materials are used. In these types of solar cells tandem junctions are fabricated in a configuration such that the resulting device is a 2-T device. As examples, 2-T devices have been fabricated in the following two and three cell configurations.

(1) a-Si:H/a-Si:H (two cell)

(2) a-Si:H/a-SiGe:H (two cell)

(3) a-Si:H/a-Si:H/a-SiGe:H (three cell)

(4) a-Si:H/ncSi:H (two cell)

(5) a-SiC/a-Si:H/a-SiGe:H (three cell)

wherein amorphous silicon is designated “a-Si:H”, amorphous silicon-germanium alloys are designated as “a-Si:Ge:H”, and micro-crystalline (or nano-crystalline) are designated as “μc-Si:H” or “nc-Si:H”.

### SUMMARY OF THE INVENTION

The present invention provides 3-T and 4-T, thin-film, Si based, solar cells and solar cell panels in which the above-mentioned current-matching-constraint is released from each constituent cell, e.g. two cells (a first a-SiH cell and a second, stable and low band gap material cell, such as nc-Si:H are separated by a layer that is light transparent. This construction provides an ultra-thin (from about 500 A to about 2000 A thick) a-Si:H top-disposed solar cell, where instability and current-matching are no longer an issue. This stable 3-T or 4-T solar cell arrangement has the potential of attaining η>16%.

### BRIEF DESCRIPTION OF THE DRAWINGS

FIG. 1 is taken from U.S. Pat. No. 6,258,408 and provides a top view of a circular, multiple chamber, vacuum deposition system of the type that may be used to manufacture solar cell devices in accordance with the present invention.

FIG. 2 is taken from U.S. Pat. No. 6,258,408 and provides a prospective view of a reel-to-reel cassette of the type used in the vacuum deposition system shown in FIG. 1.

FIG. 3 is a side schematic view of a four-terminal solar cell in accordance with the present invention wherein the top-located p-i-n cell (cell-1 and the cell that receives incoming light) contains an ultra-thin layer of a-Si:H that is from about 500 A to about 2000 A thick, wherein the bottom-located n-i-p cell (cell-2 and the cell that receives light from cell-1) contains a layer of nc-Si:H that is about 15,000 Angstroms thick, and wherein a textured ZnO, ITO or SnO₂ layer that is located on the bottom surface of a mid-located substrate provides light-scattering as light enters n-i-p cell-2 (alternately, cell-1 can be a p-i-n cell, whereupon cell-2 is an n-i-p cell).

FIG. 4 is a side schematic view of a three-terminal solar cell in accordance with the present invention wherein the top-located p-i-n cell (cell-1 and the cell that receives incoming light) contains an ultra-thin layer of a-Si:H that is from about 500 A to about 2000 A thick, wherein the bottom-located n-i-p cell (cell-2 and the cell that receives light from cell-1) contains a layer of nc-Si:H that is about 15,000 Angstroms thick, and wherein a textured and mid-located ZnO layer that provides light-scattering as light enters n-i-p cell-2 (alternately, cell-1 can be a p-i-n cell, whereupon cell-2 is an n-i-p cell).

FIG. 5 shows the efficiency of the FIG. 3 4-T solar cell in accordance with the invention having a band gap of 1.9 eV for the top cell-1 (a-Si:H), wherein most of the power is generated by the bottom cell-2 (nc-Si:H).

FIG. 6 is a process flow chart that shows a manner of manufacturing the 4-T solar cell of FIG. 3 in which both sides of a electrically non-conductive substrate, such as glass, are processed at the same time.

FIG. 7 is a process flow chart that shows a manner of manufacturing a solar cell panel in accordance with the invention, wherein each individual solar cell within the panel is of the 4-T type shown in FIG. 3, and wherein both sides of an electrically non-conductive substrate, such as glass, are processed at the same time, generally in the manner shown.

FIGS. 8A, 8B and 8C are a process flow chart that show a manner of manufacturing a 3-T solar cell panel in accordance with the invention, wherein each individual solar cell within the panel is of the 3-T type shown in FIG. 4.

FIG. 9 shows an embodiment of the invention wherein the four-terminal solar cell of FIG. 4 includes a metal support member, such as stainless steel, and an insulating layer on the metal support member.

### DETAILED DESCRIPTION OF THE INVENTION

To circumvent instability problems that are found in 2-T solar cells, the present invention provides 3-terminal and 4 terminal (4-T), thin-film, silicon-based, solar cells and solar cell panels in which the above-described current-matching-constraint is released from each constituent cell.

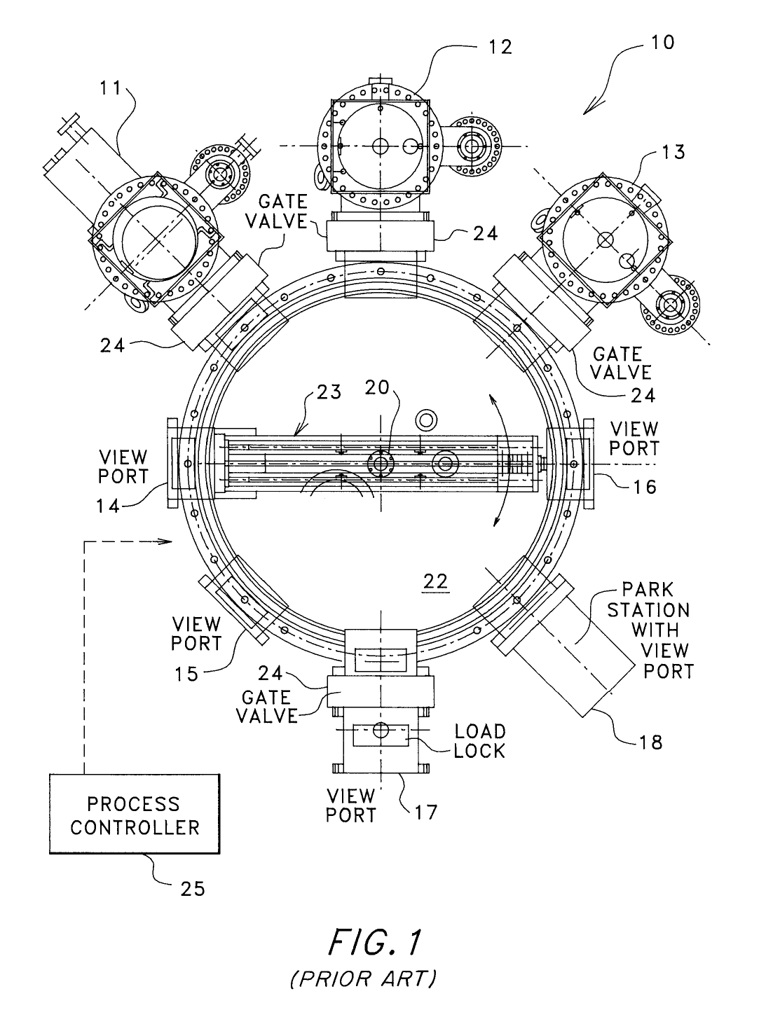

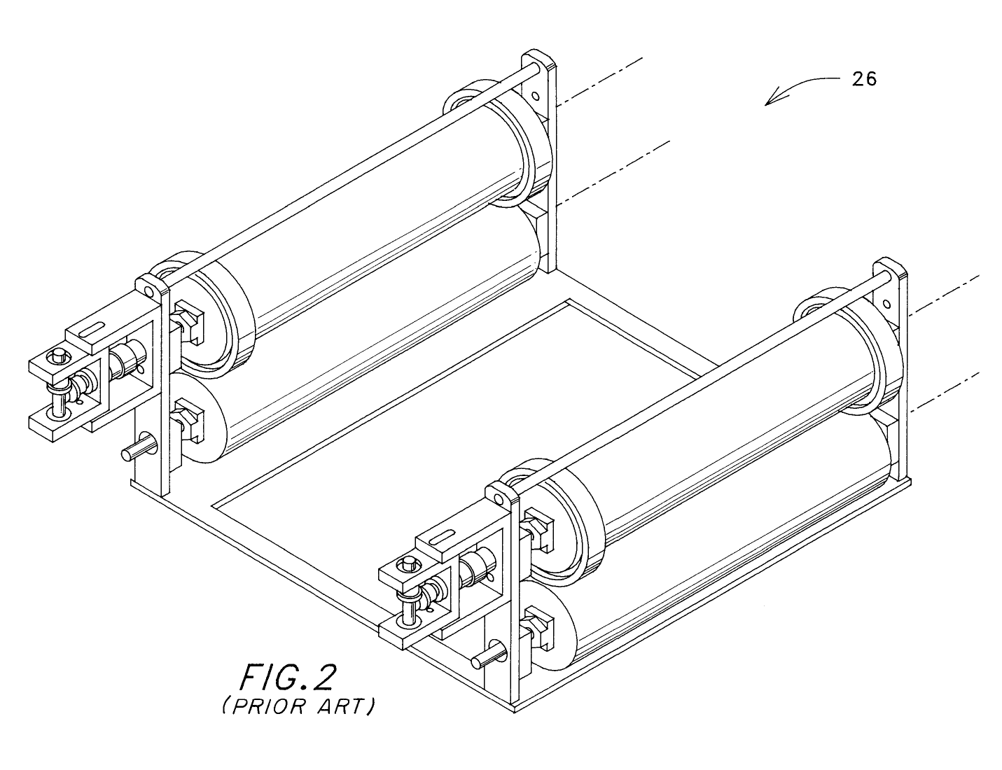

Apparatus for manufacturing solar cells and solar cell panels in accordance with this invention can be as found in any one of the four United States Patents incorporated herein by reference, and FIGS. 1 and 2 taken from U.S. Pat. No. 6,258,408 are a preferred example of such an apparatus.

FIG. 1 is a top view of a circular, multiple-chamber, vacuum deposition system 10 having three vacuum deposition chambers 11, 12 and 13, three view-port stations 14, 15 and 16, a load lock station 17, a park station 18, a disk-shaped vacuum chamber 22, a bi-directional robotic arm 23 that is contained within vacuum chamber 22 and is rotatable therein about an axis 20, and a number of gate-valves 24.

Robotic arm 23 and gate-valves 24 are controlled by a controller 25 to selectively move reel-to-reel cassette 26 (shown in FIG. 2) to selected deposition chambers, as the various layers or thin-films of solar cells/panels are deposited on a flexible substrate that extends between the two reels of reel-to-reel cassette 26, as is more completely described in U.S. Pat. No. 6,258,408.

It shown be noted that in accordance with this invention the arrangement of FIG. 1 can also be used to process rigid substrates, rather than a flexible that is carried by a reel-to reel cassette.

The present invention provides a system architecture of the type shown in FIGS. 1 and 2 that is used to fabricate thin-film silicon solar cells on a rigid or a flexible substrate. This system architecture, using the advantages of the cluster tool shown in FIGS. 1 and 2 wherein a flexible substrate is contained within a FIG. 2 cassette, provides for reel-to-reel movement of a flexible substrate.

The cassette is transported to an individual process chamber using robotic arm 23. When the entire roll of substrate within the cassette has been processed by a given process chamber, the roll is rewound, and the cassette is then transported into another chamber for further substrate-deposition.

A 3-T or a 4-T solar cell structure of the present invention (e.g. an amorphous Si cell and a stable low band gap nano-crystalline Si cell) leads to high efficiency (>15%), stable, and low cost solar cells on a flexible or rigid substrate. The use of a pulsed PECVD technique within the deposition chambers of FIG. 1 provides that the crystal structure of the nano-crystalline Si films can be altered from crystal-structure 111 to crystal-structure 220 in a controllable way at a low temperature of <170 C.

A solar cell panel in accordance with this invention comprises, for example, top-disposed a-Si:H in an n-i-p configuration, and bottom-disposed nc-Si:H in a p-i-n configuration, each cell of the panel including a transparent substrate. This panel can include a bottom-disposed and flexible stainless steel web that facilitates the manufacture of the panel using a reel-to-reel device such as is described in U.S. Pat. No. 6,258,408 wherein the deposition chambers are provided in either a circular array of chambers or a linear array of chambers.

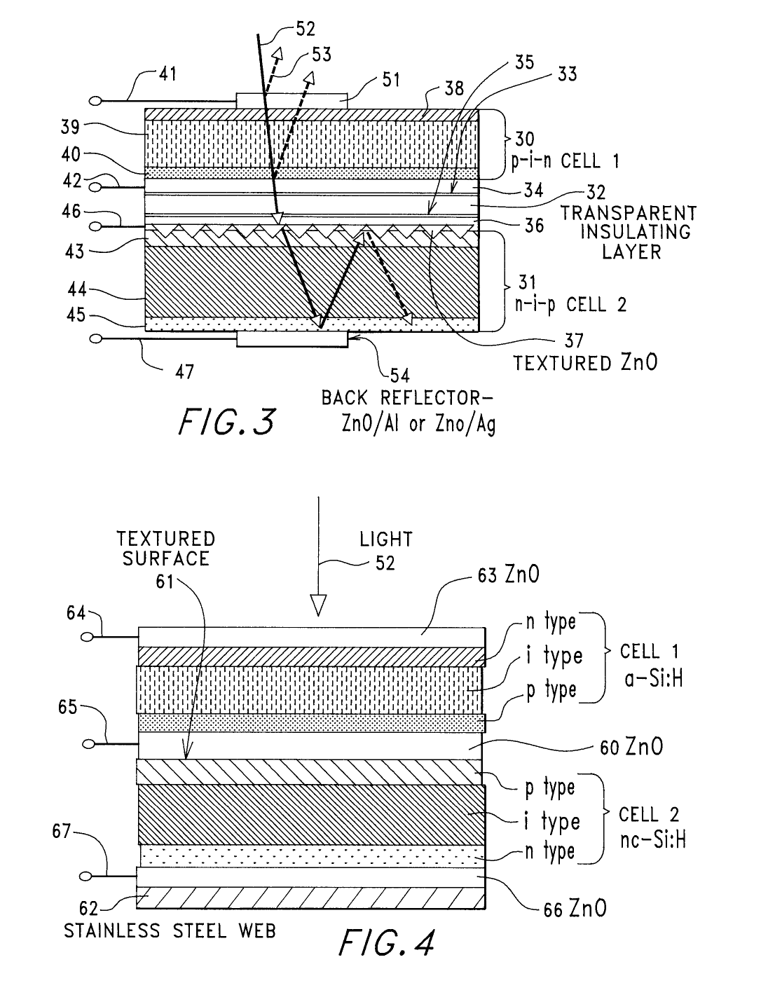

In the 4-T configuration of the invention shown in FIG. 3 a mid-located light transparent and electrically insulating layer 32 (which can be in the form of a relatively rigid glass plate having an exemplary planar size of about 1 foot by about 3 feet) is coated on its upper surface 33 with a thin zinc oxide layer 34, and is coated on its lower surface 35 with a thin zinc oxide layer 36 that is textured as is shown at 37. The thickness of these two zinc oxide coatings 34 and 36 is selected to accommodate the current densities generated within cell-1 and cell-2. For example, cell-1 may have a current density of from about 3 to about 12 milliamps per square centimeter, whereas cell-2 may have a current density of from about 10 to about 26 milliamps per square centimeter.

FIG. 3's a-Si:H cell-1 includes an n-layer 38, an i-layer 39, a p-layer 40, and first and second output terminals or connections 41 and 42.

FIG. 3's nc-Si:H cell-2 includes a p-layer 43, an i-layer 44, and an n-layer 45, and third and fourth output terminals of connections 46 and 47.

Light beams 52 enter the structure of FIG. 3 by first passing through a thin ZnO layer 51, whereupon light enters the top surface of cell-1, passes down through cell-1, passes through zinc oxide layer 34, passes through substrate 32, and pass through zinc oxide layer 43 to be scattered by texturing 37 as light enters the top-surface of cell-2. At the various surface-interfaces light can be reflected, as shown at 53, and texturing 37 operates to better contain a portion of this reflection within cell-2.

In the 4-T solar cell of FIG. 3 the two solar cells (a top-located p-i-n a-Si:H cell 30 and a bottom-located stable low band gap n-i-p nc-Si:H cell 31) are separated by a transparent and electrically insulating substrate 32, such as a glass substrate or a flexible substrate, wherein substrate 32 can be either a rigid or a flexible substrate. Note that when a 4-T device is being manufactured, and when an electrically conductive substrate such as stainless steel is used, an insulating layer such as SiNn needed between cell-1 and cell-2.

In the alternate, cell-1 of FIG. 3 can be an n-i-p cell, whereupon cell-2 is a p-i-n cell. That is, generically, cell-1 is of one conductivity-type taken from the group n-i-p and p-i-n, and cell-2 is of the other conductivity-type taken from this group.

In solar cells and solar cell panels in accordance with this invention, cell-1 (a-Si:H) can have a thickness that ranges from about 500 A to about 2000 A, with a thickness of about 1000 A being preferred, and cell-2 (nc-Si:H) can have a thickness that ranges from about 800 A to about 20,000 A, with a thickness of about 15,000 A being preferred. Stable and low band gap cell-2 is preferable formed of nc-Si:H. However other materials such as CIS, CIGS and CdTe can be used for cell-2.

The 4-T solar cell of FIG. 3 includes a back reflector or back contact 54 that is located on the bottom-surface of nc-Si:H cell-2. Reflector 54 is preferably made from ITO, ZnO, Al, Ag, Zn, ZnO/Al or (ZnO/Ag). For example, ZnO is deposited to a thickness of from about 200 A to about 800 A, followed by the deposition of Ag to a thickness of about 100 A, wherein Al can be substituted for Ag.

The a-Si:H films of cell-1 and cell-2 are deposited at the rate of about from about 1 A to about 3 A per second, preferable using the PECVD technique (e.g. using SiH₄ and H₂ gasses) capacitively coupled, operating at a fixed continuous frequency of about 13.56 MHz. This deposition can also be performed using pulsed PECVD, VHF-PECVD or HWCVD.

Doping is achieved by adding diborane (or TMB-tri-methyl boron) and methane for the p type layer and phosphine for the n type layer. SiNₓ is deposited at a temperature range of from about 100 to about 400 degrees C. using the PECVD technique and using gas mixtures of SiH₄ and NH₃ (and/or N₂). This insulator can also be formed of SiOₓ using gas mixtures of SiH₄ and N₂O, or SiONₓ using gas mixtures of SiH₄, N₂0 and N₂ or NH₃, or SiNₓ, SiOₓ, or SiONₓ using pulsed PECVD, VHF-PECVD or HWCVD.

Other materials, necessary to complete solar panels, include metallization and transparent conducting oxides (e.g. ZnO, ITO etc.) are deposited using a sputter deposition technique.

Cross contamination of as low as 1 ppm of B or P can have a deleterious effect on the performance of a device. Hence the use of a cluster tool as shown in FIG. 1 is desirable wherein multiple process chambers 11,12,13 (Modular Process Zones or MPZ's) are stationed around a central circular evacuated isolation and transfer zone 22 (ITZ). The ITZ houses an accurate and precise robotic arm 23 that works on a “pick and place” principle and serves to insert, extract and transfer a substrate from one MPZ to another, in any desired sequence. As each MPZ has a gate valve 24 located between it and the ITZ, cross contamination is prevented.

The solar cell of FIG. 3 can be made thin enough to eliminate degradation; and importantly, and in contrast to a 2-T “micro-morph” cell structure, most of the power of the FIG. 3 solar cell is generated from the stable (nc-Si:H) bottom-located cell 31, wherein it is assumed that the open circuit voltage of the bottom-located nc-Si:H cell 31 is improved to >650 mV, this being the voltage normally obtained in large grain multi-crystalline Silicon. In an illuminated state, the ultra thin a-Si:H solar cell of FIG. 3 does not exhibit instability.

The quantum efficiency (QE) of a FIG. 3 solar cell in accordance with this invention remains the same before and after about 50 hours of illumination (the same was found to be true for other parameters such as, FF, Voc, Jsc). It should be noted that within this time frame, thicker a-SiH solar cells, which are normally used in 2-T solar cell configurations, usually degrade by about 10%, and eventually saturate with a power that is about 25% lower than an initial value.

FIG. 4 shows a 3-T solar cell in accordance with the invention that is constructed much like FIG. 3, with the exception that three output terminals 64, 65 and 67 are provided, and substrate 60 that separates the cell-1 and cell-2 in FIG. 4 is an electrically conductive and transparent layer (for example a ZnO layer) whose bottom-surface 61 is textured.

The construction of FIG. 4 in accordance with the invention is much like that of FIG. 3, with the exception that the substrate that separates the two cells is an electrically non-conductive and transparent, rigid or flexible layer, and the solar cell (or panel) is supported by a bottom-disposed and rigid or flexible stainless steel foil 62 or a flexible plastic web 62 that acts as a back reflector 62 for cell-2.

Above-mentioned U.S. Pat. No. 6,258,408 provides the reel to reel cluster tool of FIGS. 1 and 2 wherein the cassette of FIG. 2 houses flexible substrate 62 having a width of 30 cm or larger. Each process chamber 11,12,13 of FIG. 1 contains reel drives and mechanisms to locate the cassette over a chemical vapor deposition zone (for example a PECVD zone) or sputtering deposition zone. Within a process chamber of FIG. 1, the reels within the cassette are physically engaged for movement of flexible substrate 62 from one reel to the other during a multi-deposition process.

At the end of a deposition event, flexible substrate 62 is returned to its original reel and locked into position, whereupon the cassette is removed from that chamber for transport to the next chamber, using robotic arm 23. Hence cross contamination of flexible substrate 62 is eliminated.

Using a pulsed PECVD technique, various types of films can be grown at a low deposition temperature (<170° C.) from quality 222 oriented nc-Si:H to predominantly 111 oriented films, and a nc-Si:H film has been uniformly developed (<+/−5%) over a substrate area of about 30 cm×40 cm. Also, a nc-Si:H solar cell can be constructed as glass/etched ZnO/nc-p type/nc-Si:H, i-layer/amorphous-n plus/ZnO/Ag with i-layer of 1.5 μm thickness to provide a solar cell efficiency of ˜8%, the individual parameters being Voc of 0.48 V, FF of 0.7 and Jsc˜24 mA cm⁻².

Relative to the efficiency of FIG. 3's 4-T solar cell in accordance with the present invention, it is desirable that the band gap of cell-1 be increased to allow more light to pass through cell-1 and then enter cell-2. By changing the H₂ dilution in the fabrication of cell-1's i-layer, the band gap of the i-layer increases to ˜1.9 eV, leading to single junction cell-1 with Voc to 0.93 V, FF˜0.75 and Jsc˜7 mA/cm² (thickness˜900 A).

With further optimization, a Voc˜1 V, FF˜0.75 and Jsc of ˜8 mA/cm² can be provided, with the result that cell-1 of the present invention is a stable cell having η˜6%. With the inclusion of a ZnO/Ag (or ZnO/Al) back reflector in cell-2, an increased response at the red end of the spectra is provided, and it is possible to achieve Jsc˜20 mA/cm² from cell-2, with Voc ˜0.45-0.47 and FF ˜0.7.

With full integration of the FIG. 3 4-T solar cell of the present invention on a glass substrate 60, a stable device efficiency of η>12% is expected. With an improvement in Voc to beyond 650 mV, and with use of antireflection coatings, stable device efficiencies of >16% are possible.

The construction of a solar cell panel that contains a number of individual solar cells of the types shown in FIGS. 3 and 4 requires that the substrate be subjected to a scribing, cutting or scratching process, such as laser scribing.

The present invention provides that a relatively large panel having the general construction shown in FIGS. 3 and 4 is preferably subjected to laser scribing. This laser scribing procedure can be performed as a relatively large FIG. 3 or 4 panel resides within a process chamber that is within the FIG. 1 system, or the relatively large FIG. 3 or 4 panel can be removed from the FIG. 1 system and inserted into a laser scribing system. Thus this invention provides a solar cell panel having multiple solar cells whose outputs are electrically connected is series, with a consequent reduction in production cost.

As stated above, in the present invention, two solar cells are separated by a substrate, a top-located light-receving cell-1 is constructed from ultra thin a-Si:H (from about 500 A to about 2000 A thick, with 1000 A being prefered), and a bottom-located cell-2 is preferable constructed from nc-Si:H about 15,000 A thick.

In some instances it may be desirable to provide solar cells of the type shown in FIGS. 3 and 4 wherein a metal support member such as rigid or flexible stainless steel is provided. The constuction and arrangement of FIG. 4 provides for this utility since member 62 comprises a stainless steel member that is either rigid or flexible.

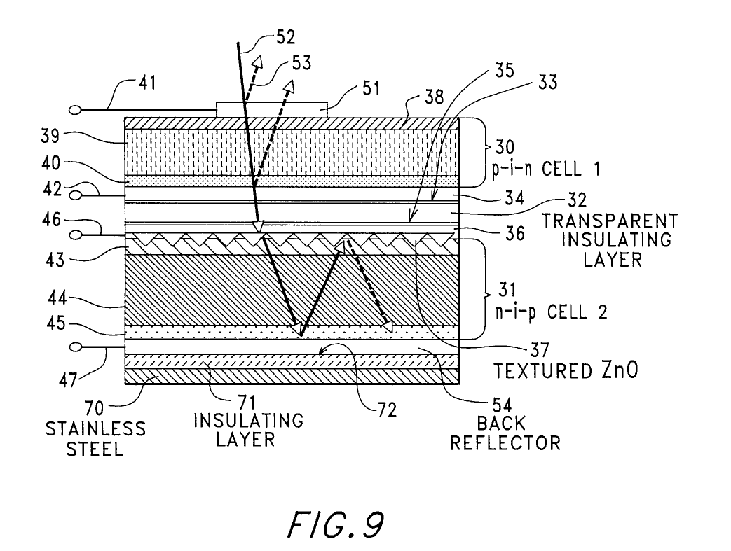

FIG. 9 provides an embodiment of the invention wherein the 3-T solar cell of FIG. 3, either as a single solar cell or as a large multi-cell panel, includes a stainless steel member 70 that is either in a rigid-form or in a flexible web-form, and includes an electrically insulating layer 71 on whose top surface 72 the back relfector 54 shown in FIG. 3 is located, it being noted that the reaminder of the FIG. 9 embodiment of the invention is as shown and described relative to FIG. 3.

In this way, both 3-T and 4-T solar cells or solar cell panels in accordance with the invention are provided for those uses in which the material-properties of a metal support, such as stainless steel, are desirable.

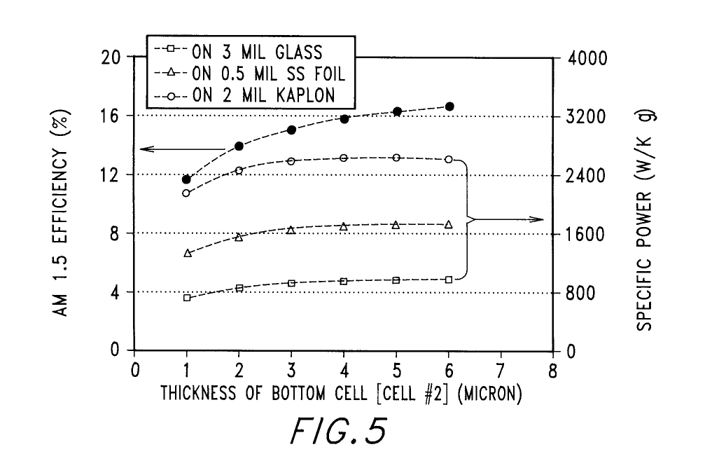

FIG. 5 shows a solar cell efficiency (>16%) of a 4 T solar cell in accordance with the invention, assuming a band gap of 1.9 eV for top cell-1 wherein top cell-1 comprises a-Si:H and it is thin enough (<1000 A) to eliminate the above described degradation. Importantly, and in contrast to a 2 T “micro-morph” cell structure, most of the power is generated from the stable (nc-Si:H) bottom cell-2.

The ultra thin (<1000 A) a-Si:H cell-1, under illumination, should not exhibit instability. It is known that the depletion width of a p-i-n junction using a-Si:H is about 3000 A. Further, the density of defect states within an a-Si:H layer increases by about an order of magnitude with illumination, and saturates to about 10¹⁷ cm⁻³. As the minority carrier diffusion length is small (<0.30 micrometers) in these types of devices, it is the charge separation of the photo generated electron-hole pairs from within the depletion width that contribute to the majority of the short circuit current. Hence, to a first order approximation, after defects have reached a saturation level, the depletion width shrinks to about ⅓ of its original value, and should remain larger than the thickness of the device, which in this case is <1000 A, and the device remains fully depleted, with the consequence that no degradation would be apparent.

Nano crystalline Silicon (nc-Si:H) materials and solar cells are generally characterized with grain size of about 200 A, at 220 orientation, band gap of ˜1. leV, crystalline fraction of 60-95%, and they exhibit a minority carrier diffusion length >l μm. Dark conductivity is ˜10⁻⁷ (ohm-cm)⁻¹ with a conductivity activation energy of ˜0.5 eV. By altering the SiH₄/H₂ gas ratio, a-Si:H-to-nc-Si:H transition takes place and a crystalline fraction of >90% can be achieved. A major factor determining opto-electronic properties is the control and elimination of O within the film. From a device point of view, critical factors are minimization of the incubation layer, control of the interfaces, and the effect of a textured substrate.

Of the known deposition techniques used for the deposition of nc-Si:H films, pulsed PECVD offers a promising approach, and using this technique various types of films can be grown at a low deposition temperature (<170 C) from device-quality nc-Si:H (220 orientation) oriented to predominantly (111) oriented films.

In order to increase the overall efficiency of the 4-T solar cell of FIG. 3, the band gap of cell-1 should be increased to allow more of the light 45 to enter cell-2. By changing the H₂ dilution in i-layer fabrication, the band gap of the i-layer can be increased to ˜1.9 eV, leading to a single-junction solar cell with Voc to 0.93 V, FF˜0.75 and Jsc˜7 mA/cm² (cell-1 thickness ˜900 A).

With the inclusion of a ZnO/Ag back reflector 54 in cell-2, an increased response at the red end of the spectra is provided, and it should be possible to achieve Jsc˜20 mA/cm² from cell-2, with Voc ˜0.45-0.47 and FF ˜0.7. With full integration of the FIG. 3 device on a glass substrate 32, a stable device efficiency of η>12% is expected. With an improvement in Voc to beyond 650 mV, and use of antireflection coatings, stable device efficiency >15% are possible.

As the deposition temperatures of cell-1 and cell-2 are lowered to less than 200 C, it is possibile to fabricate a thin stable structure on a plastic substrate, which deposition can be performed simultaneously on both sides of the substrate, i.e. cell-1 and cell-2 can be deposited simultaniously.

The present invention's reel-to-reel cassette arrangement provides a solution to making high performance solar cell devices since cross contamination is eliminated. With the incorporation of well-know laser scribing techniques, complete multi-solar-cell panels having high efficiency can be fabricated.

Numerous techniques have been used to deposit nc-Si:H, such as PECVD, VHF-PECVD, Gas Jet and HWCVD. All of these techniques result in η of 7-9%, and the so called “micro-morph” cell, using the PECVD technique, has resulted in η˜13% at a deposition rate (DR) of˜1 A per second; as the film-thickness requirement in the device (for nc-Si:H) is in the range of 1-3 μm. However, this is an impractical approach.

Using a similar deposition approach and device configuration, large-area modules have been reported with a stabilized, η of ˜10%. Using the HWCVD technique, stable devices have been reported having ˜8%, but at a DR ˜1 A per second. Using the VHF-PECVD technique, the DR has been increased to 5 A per second with η˜7%, in a single junction configuration. Using a conventional PECVD (high pressure and low substrate temperature) technique, η>9% has been achieved, but these process conditions are not conducive for production due to potential yield problems. Scale-up of VHF-PECVD is problematical, as would be expected for the Jet deposition technique also.

Hence all of these techniques confront a low deposition rate (DR), dust formation, and/or the compatibility issue of large area deposition.

Of all the deposition techniques studied in the development of nc-Si:H materials and devices, pulsed PECVD technique offers a promising approach. In this technique plasma is modulated in the range of 1 to 100 kHz, with an ON-time to OFF-time ratio of 10-50%. The time-averaged plasma properties when so modulated also differ markedly from those generated using normal continuous wave (CW) excitation used in the PECVD approach. Because discharge in the plasma is not in equilibrium, time modulation permits tuning of processing conditions, often with an improvement.

In a modified version of the pulsed PECVD technique, film growth can be altered in a rapid way (via deposition/etching cycles), to thus control the structure and eliminate weak bonds. In this technique, hydrogen, halogens or argon can be used as a diluent gas with the source gas SiH₄. Using atomic hydrogen and or halogens during the film-growth acts to modify film properties over a wide processing range (e.g deposition pressure, flow rates etc.); and an etching effect acts to reduce defect density in a-Si:H films, and to change the film structure from completely amorphous to nano-crystallites embedded in amorphous matrix.

Optical emission spectroscopy (OES) studies of the modified pulsed PECVD technique show that the concentration of atomic hydrogen in the plasma can be modulated very rapidly (microsecond level) during film growth, this enabling a modification of the growing film surface in a layer-by layer fashion. The ability to alter the growth in a layer-by-layer fashion should have an impact in the improvement of solar cell performance.

At present, and in nc-Si:H solar cells, the major limitation is the low open circuit voltage, normally around 480-500 mV. To improve this to beyond 650 mV, as obtained in multicrystalline solar cells, it is necessary to understand the limitation of grain size and passivation, which in turn dictates the transport process.

The present invention and its reel-to-reel cluster tool system provides for the low-cost manufacture of electronic devices such as solar cells on a flexible substrate. The use of a the present invention's solar cell structures, using a-Si:H and nc-Si:H solar cells, provides for the low-cost production of solar cell panels. The use of pulsed PECVD can provide layer-by-layer growth modifications, which can have an impact in the attainment of large grain size for the nc-Si:H layer, and can have implications for higher performance devices at low substrate temperatures.

The present invention provides 3-T and 4-T solar cell devices having η˜9%, and η>12%. With an improvement in Voc of the nc-Si:H layer of cell-2 to >650 mV, stable η>16% is possible. The present invention's use of 3-T and 4-T a-Si:H cell-1 and a nc-Si:H cell-2 structure provides a means of obtaining high efficiency and low cost production.

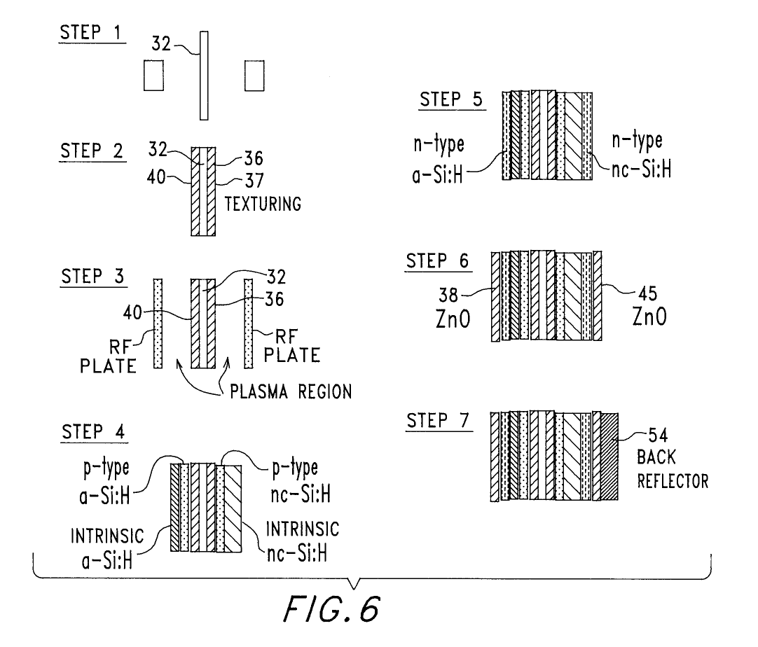

FIG. 6 is a process flow chart that shows a manner of manufacturing the 4-T solar cell of FIG. 3 in which both sides of a electrically non-conductive substrate 32, such as glass, are processed at the same time.

The following-described semiconductors a-Si:H and nc-Si:H are deposited using PECVD in gasses such as SiH₄, H₂, SiF₄, dichlorosilane and various combinations of these gasses, using frequencies from the kHz range to above 100 megahertz, and in a pulsed PECVD system the plasma can be modulated in the 1 Hz to several kHz range.

With reference to FIG. 6, in step-1 glass substrate 32 is fed into a deposition system containing a sputter chamber, and a TCO layer 40 such as ZnO is deposited on one side of substrate 32 (the cell-1 side), as a ZnO layer 36 is simultaneously sputter-deposited on the other side of substrate 32 (the cell-2 side).

It should be noted that the above-described TCO (transparent conducting oxide) layer 40 can also be ITO (indium tin oxide) or SnO₂ (tin oxide). TCO's are deposited using sputtering technique and RF frequencies, and can also be fabricated using techniques such as evaporation or electron-beam evaporation through an appropriate plasma such as oxygen.

In step-2 of FIG. 6 the ZnO-coated substrate 32 is removed from the deposition system, and ZnO coating 36 is textured at 37, for example by acid etching.

In step-3 of FIG. 6 ZnO-coated substrate 32 is introduced into a deposition system to perform semiconductor layer deposition using the PECVD technique, wherein one side 40 of ZnO-coated substrate 32 is coated with p-type a-Si and the other side 36 of ZnO-coated substrate 32 is simultaneously coated with p-type nc-Si:H.

In step-4 of FIG. 6 substrate 32 from step-3 is coated on the p-type a-Si:H side of substrate 32 with intrinsic a-Si:H, as the p-type nc-Si:H side of substrate 32 is simultaneously coated with intrinsic nc-Si:H.

By altering process conditions between the two RF electrodes of a PECVD system, a-Si on one side of substrate 32 and nc-Si:H on the other side of substrate 32 can be deposited simultaneously. Since the a-Si:H layer and the nc-Si:H layer are of different thickness, by turning off power at the appropriate time, these different thickness can be achieved.

PECVD process conditions, such as RF power, perhaps pulsed on one side of substrate 32 and non-pulsed in the other side of substrate 32, different anode-cathodes distance on opposite sides of substrate 32, and different RF electrode configurations on opposite sides of substrate 32 allow different confinement and residence time for gasses on opposite sides of substrate 32. By controlling these PECVD conditions, the material phase can be changed from a-Si:H to nc-Si:H.

In step-5 of FIG. 6 substrate 32 from step-4 is simultaneously coated on its intrinsic a-Si:H side with n-type a-Si:H, and on its intrinsic nc-Si:H side with n-type nc-Si:H.

In step-6 of FIG. 6 substrate 32 from step-5 is placed into a sputtering system for the simultaneous deposition of two ZnO layers 38 and 45, and as a last step-7 of FIG. 6 the cell-2 side of substrate 32 from step-6 is coated with a reflecting layer 54.

While simultaneous coating is described above, the various above-described coatings can be formed in a sequential fashion, and the deposition systems, sputtering and/or PECVD, can be configured in a horizontally or vertically.

Thickness of the above-described layers are as shown below, but are not limited thereto;

ZnO layers 500 A to 8000 A

p-type a-Si:H and p-type nc-Si:H 40 A to 200 A

intrinsic a-Si: H 100 A to-2000 A

intrinsic nc-Si:H 0.5 mm to 5 mm

n-type a-Si:H and n-type nc-Si:H 40 A to 400 A

back reflector layer 54 1000 A to 10000 A.

Also, instead of, or in addition to, the use of ZnO texture 37, as above-described, the surface of metal back reflector 54 that faces cell-2 can be textured by controlling the sputtering process by which back reflector 54 is deposited.

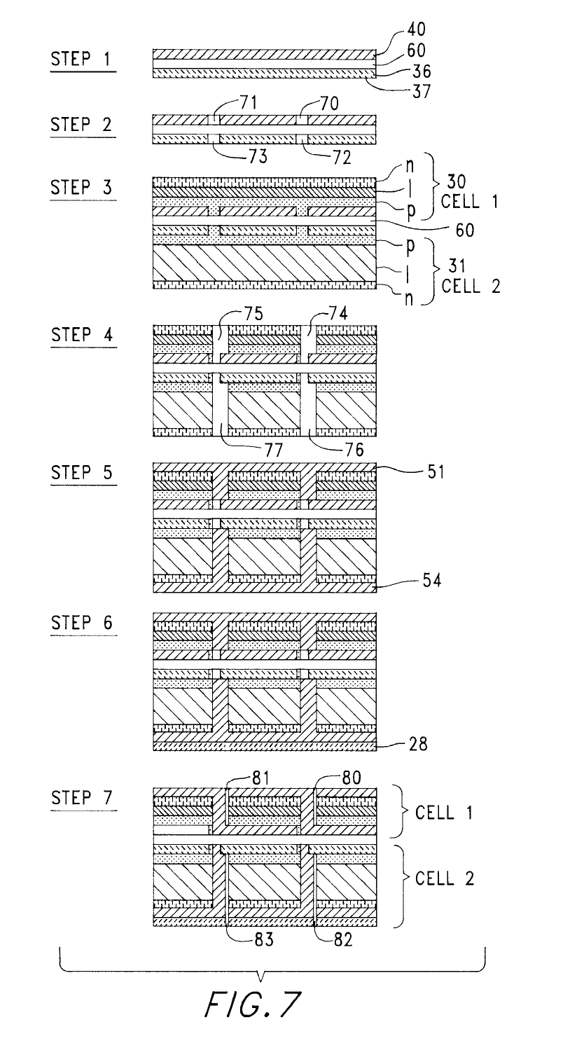

FIG. 7 is a process flow chart that shows a manner of manufacturing a 4-T solar cell panel in accordance with the invention, wherein each individual solar cell within the panel is of the 4-T type shown in FIG. 3, and wherein both sides of an electrically non-conductive substrate, such as glass, are processed at the same time, generally in the manner shown in FIG. 6.

In step-1 of FIG. 7, a glass or ZnO substrate 60 is fed into a sputter chamber, and the two opposite sides of substrate 60 are simultaneously deposited with a TCO layer 36 and 40, for example ZnO.

As a second portion of step-1, TCO-coated substrate 60 is then removed from the sputter chamber, and, as an option, TCO layer 36 is textured at 37, for example by acid etching.

In step-2 of FIG. 7, the TCO-coated substrate 60 is laser-scribed as shown at 70, 71, 72 and 73. This laser-scribing operation separates the TCO coating on substrate 60 into a number of individual areas, each area of which will correspond to an individual 4-T solar cell of the type shown in FIG. 3.

In step-3 of FIG. 7, the laser-scribed substrate from step-2 is introduced into a chemical vapor deposition system to perform semiconductor layer depositions, preferable using the PECVD technique. In this way a n-i-p cell-1 is formed on one side of the substrate as a p-i-n cell-2 is formed on the other side of the substrate. Typically the TCO coating on substrate 60 is about 600 A thick, the total thickness of the n-i-p cell-1 is about 1200 A, and the total thickness of the p-i-n cell-2 is about 15000 A. Hence the gap at the laser scribing site would tend to be filled by the p-i-n structure.

Preferable in step-3 of FIG. 7 the two sides of substrate 60 are simultaneously coated, the cell-1 side with a-Si:H, and the cell-2 side with nc-Si:H. By altering process conditions between the two RF electrodes (not shown) a-Si:H on the cell-1 one side of substrate 60, and nc-Si:H on the cell-2 side of substrate 60, are deposited simultaneously. Since the thickness of the a-Si:H layer and the nc-Si:H layer are different, by turning off power at the appropriate time, the desired thickness are provided.

In addition, in step-3 of FIG. 7, other process conditions can be controlled, for example RF power, perhaps pulsed on one side of substrate 60 and non-pulsed in the other side of substrate 60, anode-cathodes distances of opposite side of substrate 60, different RF electrode configurations on opposite sides of substrate 60 will allow different confinement and residence time for gasses. By altering process conditions such as these, the deposited materials phase can be controlled to a-be Si:H or nc-Si:H.

In step-4 of FIG. 7, substrate 60 of step-5 is removed from the PECVD system and it is laser scribed at 73, 74, 75 and 76, again to in a manner to form a number of individual areas, each area of which will correspond to an individual 4-T solar cell of the type shown in FIG. 3.

In step-5 of FIG. 7, substrate 60 of step-4 is reentered into a sputtering system for deposition of ZnO layers 51 and 54.

In step-6 of FIG. 7, the cell-2 side of the structure of FIG. 5 is sputter-coated with a metal layer at 78 to form a reflector for cell-2.

As a final step-7 of the process shown in FIG. 7, the substrate from step-6 is laser scribed at 08, 81, 82 and 83 to form a series-connected solar cell panel in accordance with the invention.

While the above-description of FIG. 7 preferably relates to simultaneous coating operations, these coatings can be performed in sequential fashion. In addition, the sputtering and/or PECVD deposition systems can be configured in either a horizontal or a vertical configuration. In addition, the above described scribing operations can be accomplished via laser scribing, mechanical scribing or using patterning techniques.

It is desired that cell-2 include a textured surface, since with back reflector 78 for cells-2, light entering cell-2 is refracted, and a longer light path is provided within the nc-Si:H absorbing material of cell-2, this resulting in reduced material usage.

Also, instead of, or in addition to, texturing the ZnO side of cell-2, texturing can be provided by back reflector 78. For example, metal layer 78 can be textured using a sputtering process wherein the process is altered, for example the deposition temperature is altered.

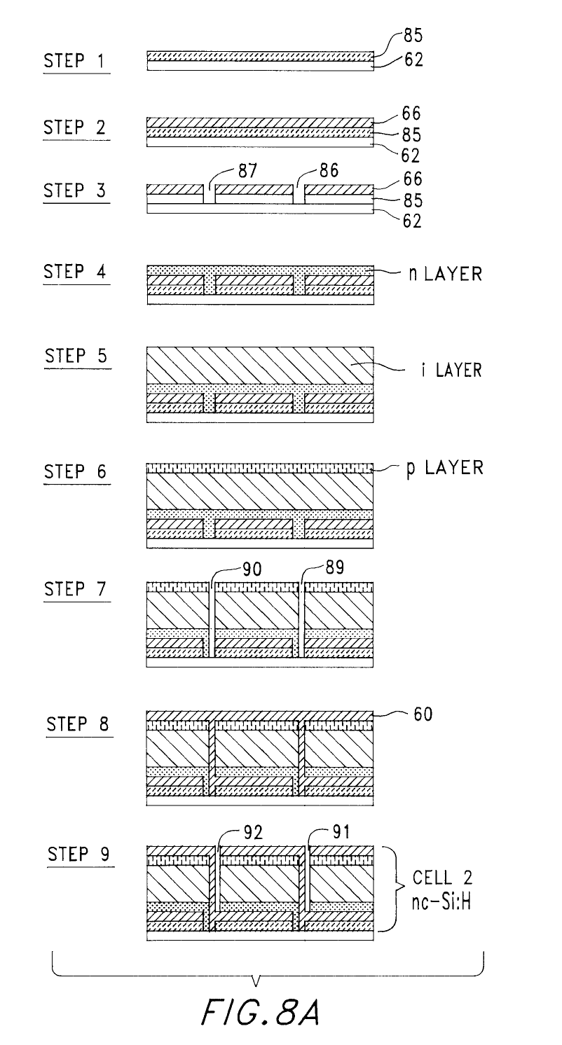

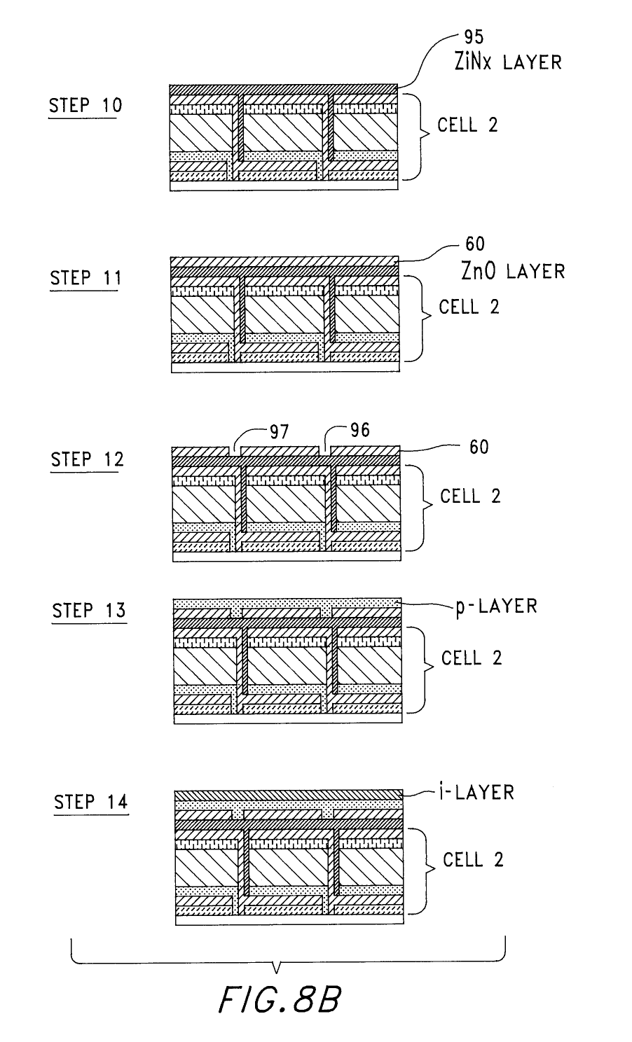

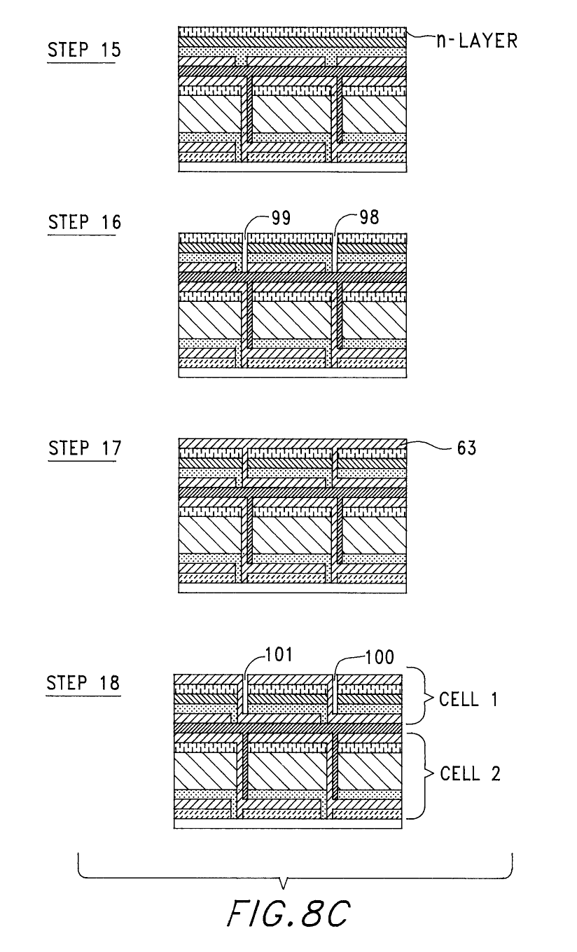

FIGS. 8A, 8B and 8C provide a process flow chart that shows a manner of manufacturing a 3-T or 4-T solar cell panel in accordance with the invention, wherein each individual solar cell within the panel is of the 3-T type shown in FIG. 4 or of the 4-T type shown in FIG. 3.

In step-1 of FIG. 8A, a stainless steel substrate 62 is fed into a sputter chamber, and the top side of substrate 62 is deposited with a metal reflector layer 85, this metal layer 85 comprising the above-described reflector for cell-2 of the FIG. 4 structure.

As mentioned above, when an electrically conductive substrate 62 is used, substrate 62 and layer 85 are separated by an electrically insulating layer, for example an SiNx layer.

An alternative approach is that the electrically conductive substrate is cut into strips, and that the cells within each strip are rejoined to provide an electrical series-connection thereof. In this case the scribing steps (to be described) can be omitted since the strips that each contain a cell-1 and a cell-2 are subsequently reconnected in series. This alternative arrangement is useful when flexible foil 62 is an electrically conductive material such as stainless steel or aluminum.

In step-2 of FIG. 8A, a ZnO layer 66 is sputter-coated on metal layer 85, and in step-3 of FIG. 8 the assembly of step-2 is laser-scribed as shown at 86 and 87 to separates the ZnO layer 66 into a number of individual areas, each area of which will correspond to an individual 3-T solar cell of the type shown in FIG. 4.

In steps-4, 5 and 6 of FIG. 8A, the laser-scribed substrate from step-2 is introduced into a chemical vapor deposition system to perform semiconductor layer depositions, preferable using the PECVD technique. More specifically, in step 4 the n-type nc-Si:H layer of FIG. 4's cell-2 is deposited, in step 5 the i-type nc-Si:H layer of FIG. 4's cell-2 is deposited, and in step 6 the p-type nc-Si:H layer of FIG. 4's cell-2 is deposited.

In step-7 of FIG. 8A, the assemble step-6 removed from the PECVD system and it is laser scribed at 89 and 90, again to in a manner to form a number of individual areas, each area of which will correspond to an individual 3-T solar cell of the type shown in FIG. 4.

In step-8 of FIG. 8A, the assemble of step 7 is reentered into a sputtering system for deposition of ZnO layer 60 shown in FIG. 4.

In step 9 of FIG. 8A, the assemble of step-8 is laser scribed at 91 and 92, again in the manner that will provide a number of individual areas, each area of which will correspond to an individual 3-T solar cell of the type shown in FIG. 4.

This completes the formation of FIG. 4's cell-2.

In steps-10 and 11 of FIG. 8B an electrically insulating SiNₓ layer 95 and a ZnO layer 60 (see FIG. 4) are applied to the assemble of step-9

In step-12 of FIG. 8B the assemble of step-11 is laser scribed at 96 and 97 again in the manner that will provide a number of individual areas, each area of which will correspond to an individual 3-T or 4-T solar cell of the type shown in FIGS. 4 and 3.

In steps-13, 14 and 15 of FIGS. 8B and 8C, the laser-scribed substrate from step-12 is introduced into a chemical vapor deposition system to perform semiconductor layer depositions, preferable using the PECVD technique. More specifically, in step 13 the p-type a-Si:H layer of cell-1 is deposited, in step 14 the i-type a-Si:H layer of cell-1 is deposited, and in step 15 the n-type a-Si:H layer of cell-1 is deposited.

In step-16 of FIG. 8C, the assemble of step-15 is laser scribed at 98 and 99, again in the manner that will provide a number of individual areas, each area of which will correspond to an individual 3-T or 4-T solar cell of the type shown in FIGS. 4 and 3.

In step-17 of FIG. 8C a ZnO layer 63 is sputter deposited on the assemble of step-15.

As a final step-18 of FIG. 8C, , the assemble of step-17 is laser scribed at 100 and 101, again in the manner that will provide a number of individual areas, each area of which will correspond to an individual 3-T or 4-T solar cell of the type shown in FIGS. 4 and 3.

From the above detailed description of the invention it can be seen that the invention provides 3-T and 4-T solar cells and solar cell panels wherein the current-matching-constraint is released from each constituent cell the makes up the solar cells and solar cell panels.

1. A unitary solar cell having two cells, comprising:
a first cell having a first layer of a-Si:H from about 500 A to about 2000 A thick, said first layer having a top-surface through which light enters said unitary solar cell and having a bottom-surface through which light exits said first layer, and said first layer having one of a n-i-p or a p-i-n configuration in a direction from said top-surface to said bottom-surface of said first layer;
a light transparent layer having a top surface engaging said bottom surface of said a-Si:H layer and having a bottom surface; and
a second cell having a second layer selected from the group nc-Si:H, CIS, CIGS and CdTe from about 800 A to about 20,000 A thick, said second layer having a top-surface engaging said bottom-surface of said light transparent layer and through which light enters said second cell from said first cell, said second layer having a bottom-surface, and said second layer having the other of said n-i-p or said p-i-n configuration in a direction from said top surface to said bottom surface of said second layer.

2. The solar cell of claim 1 wherein said second layer is nc-Si:H.

3. The solar cell of claim 2 including a light reflecting layer on said bottom-surface of said second layer.

4. The solar cell of claim 2 wherein said a-Si:H layer is about 1000 A thick and said second layer is nc-Si:H about 15,000 A thick.

5. The solar cell of claim 4 including a light reflecting layer on said bottom-surface of said nc-Si:H layer.

6. The solar cell of claim 5 wherein said light transparent layer is electrically conductive, including:
a first electrically conductive and light transparent layer having a top-surface through which light enters said unitary solar cell, and having a bottom-surface located on said top-surface of said a-Si:H layer;
a first output connection connected to said first electrically conductive layer;
a second output connection connected to said light transparent layer;
a second electrically conductive layer intermediate said bottom-surface of said nc-Si:H layer and said light reflecting layer; and
a third output connection connected to said second electrically conductive layer.

7. The solar cell of claim 6 including:
a substrate having a top-surface supporting said light reflecting layer;
wherein said light reflecting layer is sputter deposited on said top-surface of said substrate;
wherein said second electrically conductive layer is sputter deposited on said light reflecting layer;
wherein said nc-Si:H layer is chemical vapor deposited on said second conductive layer;
wherein said light transparent and electrically conductive layer is sputter deposited on said nc-Si:H layer;
wherein said a-Si:H layer is chemical vapor deposited on said light transparent and electrically conductive layer; and
wherein said first electrically conductive layer is sputter deposited on said a-Si:H layer.

8. The solar cell of claim 5 wherein said light transparent layer comprises an light transparent and electrically non-conductive substrate, including:
a first electrically conductive and light transparent layer having a top-surface through which light enters said unitary solar cell, and having a bottom-surface located on said top-surface of said a-Si:H layer;
a first output connection connected to said first electrically conductive layer; a second electrically conductive and light transparent layer located intermediate said a-Si:H layer and said substrate;
a second output connection connected to said second electrically conductive layer;
a third electrically conductive and light transparent layer located intermediate said substrate and said nc-Si:H layer, said third electrically conductive and light transparent layer having a textured surface adjacent to said nc-Si:H layer;
a third output connection connected to said third electrically conductive layer;
a fourth electrically conductive and light transparent layer located intermediate said nc-Si:H layer and said reflector light reflecting layer; and
a fourth output connection connected to said fourth electrically conductive layer.

9. The solar cell of claim 8 wherein;
said second and third electrically conductive and light transparent layers are sputter deposited on opposite sides of said substrate;
wherein said a-Si:H layer is chemical vapor deposited on said second electrically conductive and light transparent light transparent layer;
wherein said nc-Si:H layer is chemical vapor deposited on said third electrically conductive and light transparent layer;
wherein said first electrically conductive and light transparent layer is sputter deposited on said a-Si:H layer;
wherein said fourth electrically conductive and light transparent layer is sputter deposited on said nc-Si:H layer; and
wherein said light reflecting layer is sputter deposited on said fourth electrically conductive and light transparent layer.

10. The solar cell of claim 1 wherein a top-surface of said light reflecting layer engages said bottom-surface of said second layer, including:
an electrically non-conductive layer having a top-surface engaging a bottom-surface of said light reflecting layer; and
a metal layer engaging a bottom-surface of said electrically non-conductive layer.

11. The solar cell of claim 10 wherein said metal layer is a flexible stainless steel foil-like layer.

12. The solar cell of claim 11 wherein said second layer is nc-Si:H.

13. A method of making a unitary solar cell having two cells, comprising the steps of:
providing a light transparent substrate having a first and a second surface;
depositing an a-Si:H layer of a first conductivity type selected from the group n-type and p-type on said first surface of said substrate;
depositing an nc-Si:H layer of a said first conductivity type on said second surface of said substrate;
depositing an intrinsic layer of a-Si:H layer on said a-Si:H layer of a said first conductivity type;
depositing an intrinsic layer of nc-Si:H layer on said nc-Si:H layer of a said first conductivity type;
depositing an a-Si:H layer of a second conductivity type on said intrinsic layer of a-Si:H, to form a first cell having a first-conductivity-type layer, an intrinsic layer, and a second-conductivity-type layer, and having a thickness of from about 500 A to about 2000 A thick; and
depositing an nc-Si:H layer of said second conductivity type on said intrinsic layer of nc-Si:H, to form a second cell having a first-conductivity-type layer, an intrinsic layer, and a second-conductivity-type layer, and having a thickness of from about 800 A to about 20,000 A thick;
said first cell having a first surface that comprises a-Si:H layer of a second conductivity type through which light enters said unitary solar cell and having a second surface that comprises a a-Si:H layer of said first conductivity type through which light exits said first cell, traverses said light transparent substrate, and enters a first surface of said second cell having an nc-Si:H layer of a said first conductivity type.

14. The method of claim of claim 13 including the steps of:
providing said light transparent substrate as a light transparent and electrically conductive substrate;
providing a first electrically conductive and light transparent layer on said a-Si:H layer of said second conductivity type;
providing a first output connection connected to said first electrically conductive layer;
providing a second output connection connected to said substrate;
providing a second electrically conductive layer on said a-Si:H layer of said second conductivity type and said light reflecting layer; and
providing a third output connection connected to said second electrically conductive layer.

15. The method of claim 14 including the steps of:
chemical vapor depositing said a-Si:H layers and said nc-Si:H layers; and
sputter depositing said electrically conductive and light transparent layers.

16. The method of claim 15 including the step of:
providing a light reflecting layer on said second electrically conductive layer.

17. The method of claim 16 wherein said first cell is about 1000 A thick and said second cell is nc-Si:H about 15,000 A thick.

18. The method of claim 13 including the steps of:
providing said substrate as a light transparent and electrically non-conductive substrate;
providing a first electrically conductive and light transparent layer on said a-Si:H layer of said second conductivity type;
providing a first output connection connected to said first electrically conductive layer;
providing a second electrically conductive and light transparent layer intermediate said a-Si:H layer of a first conductivity type and said substrate;
providing a second output connection connected to said second electrically conductive layer;
providing a third electrically conductive and light transparent layer intermediate said substrate and said nc-Si:H layer of said first conductivity type;
providing a third output connection connected to said third electrically conductive layer;
providing a fourth electrically conductive and light transparent layer located on said nc-Si:H layer of said second conductivity type; and
providing a fourth output connection connected to said fourth electrically conductive layer.

19. The method of claim 18 including the steps of:
chemical vapor depositing said a-Si:H layers and said nc-Si:H layers; and
sputter depositing said electrically conductive and light transparent layers.

20. The method of claim 19 including the step of:
providing a light scattering layer in association with said second cell.

21. The method of claim 20 wherein said first cell is about 1000 A thick and said second cell is nc-Si:H about 15,000 A thick.

22. A method of making a solar cell panel having a plurality of individual solar cells that are separated by a pattern-of-paths, wherein each of said individual solar cells comprises a solar-cell-stack having a first-cell and a second-cell, the method comprising the steps of:
providing a light transparent and electrically non-conductive substrate having a first and a second surface;
depositing a first light transparent and electrically conductive layer on said first surface of said substrate;
depositing a second light transparent and electrically conductive layer on said second surface of said substrate;
scribing said first and second transparent and electrically conductive layers to form patterns therein that correspond to said pattern-of-paths;
depositing an a-Si:H layer of a first conductivity type selected from the group n-i-p and p-i-n on said patterned first transparent and electrically conductive layer, to thereby form said first-cell configuration;
depositing an nc-Si:H layer of a second conductivity type selected from the group n-i-p and p-i-n on said patterned second transparent and electrically conductive layer, to thereby form said second-cell configuration;
scribing each of said a-Si:H layer and nc-Si:H layer to form patterns therein corresponding to said pattern-of-paths;
depositing a third light transparent and electrically conductive layer on said patterned a-SI:H layer;
depositing a fourth light transparent and electrically conductive layer on said patterned nc-SI:H layer; and
scribing each of said third and fourth light transparent and electrically conductive layers to form patterns therein corresponding to said pattern-of-paths;
to thereby form a plurality of individual solar cell, each individual solar cell having a first-cell of one conductivity type through which light enters said solar cell panel, and then enters a second-cell having an opposite conductivity type.

23. The method of claim 22 including the step of:
providing a light scattering/reflecting means for each of said second-cells.

24. The method of claim 22 including the steps of:
providing a first output connection;
connecting said first output connection to said first light transparent and electrically conductive layer;
providing a second output connection;
connecting said second output connection to said second light transparent and electrically conductive layer;
providing a third output connection;
connecting said third output connection to said third light transparent and electrically conductive layer; and
providing a fourth output connection;
connecting said fourth output connection to said fourth light transparent and electrically conductive layer.

25. The method of claim 24 including the step of:
providing a light scattering/reflecting means for each of said second-cells.

26. The method of claim 25 including the steps of:
simultaneously depositing said first light transparent and electrically conductive layers;
simultaneously depositing said a-Si:H layer and said nc-Si:H layers; and
simultaneously depositing said third and fourth light transparent and electrically conductive layers.

27. The method of claim 26 wherein said light transparent and electrically conductive layers are sputter-deposited, and wherein said Si:H layer and said nc-Si:H layer are chemical vapor deposited.

28. The method of claim 27 wherein each of said first-cells of said one conductivity type are from about 500 A to about 2000 A thick, and wherein each of said second-cells of said opposite conductivity type are from about 800 A to about 20,000 A thick.

29. A method of making a solar cell panel having a plurality of individual solar cells that are separated by a pattern-of-paths, wherein each of said individual solar cells comprises a solar-cell-stack having a first-cell and a second-cell, the method comprising the steps of:
providing a substrate having an electrically insulating surface;
depositing a first light transparent and electrically conductive layer on said surface of said substrate;
scribing said first transparent and electrically conductive layer to form a pattern therein that corresponds to said pattern-of-paths;
depositing an nc-Si:H layer of a first conductivity type selected from the group n-i-p and p-i-n on said patterned first transparent and electrically conductive layer, to thereby form a second-cell;
scribing said nc-Si:H layer in a pattern that corresponds to said pattern-of-paths, to thereby form a plurality of individual second-cells;
depositing a second light transparent and electrically conductive layer on said patterned nc-Si:H layer;
scribing said second transparent and electrically conductive layer to form a pattern therein that corresponds to said pattern-of-paths;
depositing an a-Si:H layer of an opposite conductivity type selected from the group n-i-p and p-i-n on said patterned second transparent and electrically conductive layer, to thereby form a first-cell;
scribing said a-Si:H layer in a pattern that correspond to said pattern-of-paths, to thereby form a plurality of individual first-cells;
depositing a third light transparent and electrically conductive layer on said patterned a-Si:H layer; and
scribing said third transparent and electrically conductive layer to form a pattern therein that correspond to said pattern-of-paths;
to thereby form a plurality of individual solar cells, each individual solar cell having a first-cell of said first conductivity type through which light enters said solar cell panel, and then enters a second-cell of said opposite conductivity type.

30. The method of claim 29 including the step of:
providing a light scattering/reflecting means for each of said second-cells.

31. The method of claim 29 including the steps of:
providing a first output connection;
connecting said first output connection to said first light transparent and electrically conductive layer;
providing a second output connection;
connecting said second output connection to said second light transparent and electrically conductive layer;
providing a third output connection; and
connecting said third output connection to said third light transparent and electrically conductive layer.

32. The method of claim 31 wherein said light transparent and electrically conductive layers are sputter-deposited, and wherein said Si:H layer and said nc-Si:H layer are chemical vapor deposited.

33. The method of claim 32 including the step of:
providing a light scattering/reflecting means for each of said second-cells.

34. The method of claim 33 wherein each said first-cells are from about 500 A to about 2000 A thick, and wherein each of said second-cells are from about 800 A to about 20,000 A thick.

35. A unitary solar cell having a first and a second cell, comprising:
a light transparent and electrically non-conductive substrate having a first and a second surface;
a first electrically conductive layer on said first surface of said substrate;
a second electrically conductive layer on said second surface of said substrate;
a first cell having an a-Si:H layer from about 500 A to about 2000 A thick on said first electrically conductive layer, said first cell having one of an n-i-p or p-i-n configuration in a direction away from said first electrically conductive layer;
a second cell having an nc-Si:H layer from about 800 A to about 22000 A thick, said second cell having the other of said n-i-p or p-i-n configuration in a direction away from said second electrically conductive layer;
said first cell having a first surface through which light enters said unitary solar cell and having a second surface through which light exits said first cell, traverses said substrate, and enters a first surface of said second cell;
a light reflecting layer on a second surface of said second cell;
an electrically non-conductive layer on said light reflecting layer; and
a metal layer on said electrically non-conductive layer.

36. The unitary solar cell of claim 35 wherein said metal layer is stainless steel.

37. The unitary solar cell of claim 36 wherein said stainless steel layer is flexible.

38. A unitary solar cell having a first and a second cell, comprising:
a light transparent and electrically non-conductive substrate having a first and a second surface;
a first electrically conductive layer on said first surface of said substrate;
a second electrically conductive layer on said second surface of said substrate;
a first cell having an a-Si:H layer from about 500 A to about 2000 A thick on said first electrically conductive layer, said first cell having one of an n-i-p or p-i-n configuration in a direction away from said first electrically conductive layer;
a second cell having an nc-Si:H layer from about 800 A to about 22000 A thick, said second cell having the other of said n-i-p or p-i-n configuration in a direction away from said second electrically conductive layer;
said first cell having a first surface through which light enters said unitary solar cell and having a second surface through which light exits said first cell, traverses said substrate, and enters a first surface of said second cell;
a light reflecting layer on a second surface of said second cell;
an electrically non-conductive layer on said light reflecting layer; and
a metal layer on said electrically non-conductive layer.

39. The unitary solar cell of claim 38 wherein said metal layer is stainless steel.

40. The unitary solar cell of claim 39 wherein said stainless steel layer is flexible.
